(19) United States
(12) Patent Application Publication
(10) Pub. No.: US 2025/0160023 A1
(43) Pub. Date: May 15, 2025

(54) LIGHT RECEIVING DEVICE AND ELECTRONIC APPARATUS

(71) Applicant: SONY SEMICONDUCTOR SOLUTIONS CORPORATION, Kanagawa (JP)

(72) Inventors: Tomoharu OGITA, Kanagawa (JP); Kaito YOKOCHI, Kanagawa (JP)

(73) Assignee: SONY SEMICONDUCTOR SOLUTIONS CORPORATION, Kanagawa (JP)

(21) Appl. No.: 18/839,216

(22) PCT Filed: Feb. 6, 2023
(86) PCT No.: PCT/JP2023/003813

§ 371 Date: Aug. 16, 2024

(30) Foreign Application Priority Data
Feb. 28, 2022 (JP) 2022-030028

(51) Int. Cl. H10F 39/00

(52) U.S. Cl. CPC H10F 39/8063; H10F 39/8023; H10F 39/811

(57) ABSTRACT

A light receiving device according to one embodiment of the present disclosure is a light receiving device including a plurality of pixels, each of the pixels including: a multifocal optical member having a plurality of optical axes; a semiconductor layer that receives light that is in a predetermined wavelength range and has passed through the optical member, to perform photoelectric conversion; and a transmission suppressor that suppresses, on a first surface, on a side opposite to a light incident side, of the semiconductor layer, transmission of the light through the semiconductor layer.

### TECHNICAL FIELD

The present disclosure relates to a light receiving device and an electronic apparatus.

### BACKGROUND ART

Some light receiving devices are known to have a transmission suppressor provided on a circuit surface serving as a side that is opposite to a light receiving surface of a semiconductor layer. The transmission suppressor suppresses transmission through the semiconductor layer of light that has entered the semiconductor layer from the light receiving surface. However, in the light receiving device including the transmission suppressor, in general, an on-chip lens being an optical member has only one optical axis with respect to one pixel. This may cause zero-order light to hit a multiplication region section disposed at a pixel center. Thus, there is a possibility that light may pass through the semiconductor layer from the pixel center without sufficiently hitting the transmission controller.

### CITATION LIST

### Patent Literature

PTL 1: International Publication No. WO2020-012984

### SUMMARY OF THE INVENTION

Meanwhile, in a configuration simply formed to cause one optical axis to pass through the transmission suppressor, a photoelectric conversion efficiency may be reduced, or decentering of a region in which no transmission suppressor is provided may be required. For example, in an avalanche photodiode (APD), decentering of the multiplication region section in which no transmission suppressor is provided causes asymmetry of a density of carriers generated through photoelectric conversion, and thus there is a possibility that the measurement accuracy may be reduced.

It is desirable to provide a light receiving device and an electronic apparatus that each make it possible to suppress entry of zero-order light in a region without a transmission suppressor, while suppressing reduction of measurement accuracy.

A light receiving device according to one embodiment of the present disclosure is a light receiving device including a plurality of pixels, each of the pixels including: a multifocal optical member having a plurality of optical axes; a semiconductor layer that receives light that is in a predetermined wavelength range and has passed through the optical member, to perform photoelectric conversion; and a transmission suppressor that suppresses, on a first surface, on a side opposite to a light incident side, of the semiconductor layer, transmission of the light through the semiconductor layer.

An electronic apparatus according to one embodiment of the present disclosure includes the above-described light receiving device according to the one embodiment of the present disclosure.

### BRIEF DESCRIPTION OF DRAWING

FIG. 1 is a block diagram illustrating a schematic configuration example of a light receiving device.

FIG. 2 is a diagram illustrating a configuration example of a pixel provided in the light receiving device to which the present technique is applied.

FIG. 3 is a BB cross-sectional diagram of FIG. 2.

FIG. 4 is a CC cross-sectional diagram of FIG. 2.

FIG. 5 is a side diagram of a multiplication region section.

FIG. 6 is a diagram illustrating another configuration example of a multifocal optical member.

FIG. 7 are diagrams illustrating configuration examples of a unit in which on-chip lenses are disposed on an image-plane phase pixel.

FIG. 8 is a diagram illustrating a structure example of a transmission suppressor.

FIG. 9 is a diagram illustrating a structure example of a transmission suppressor obtained by a dummy electrode.

FIG. 10 is a diagram illustrating a configuration example of a unit in which color filters are disposed in a Bayer layout.

FIG. 11 are diagrams illustrating planar shape examples of the multiplication region section.

FIG. 12 are diagrams illustrating a configuration example of a pixel according to a second embodiment.

FIG. 13 is a cross-sectional diagram illustrating an example of a color filter layer in a case where the pixels are formed as an RGB-IR imaging sensor.

FIG. 14 is a cross-sectional diagram of a pixel according to a third embodiment.

FIG. 15 is a plan diagram illustrating a configuration example of a portion of a signal extractor of the pixel.

FIG. 16s are diagrams illustrating a configuration example of a pixel according to a fourth embodiment.

FIG. 17 is a block diagram illustrating a configuration example of a ranging module that outputs ranging information with use of the light receiving device.

FIG. 18 is a block diagram of an example of an indirect time-of-flight sensor to which the present technique is applied.

FIG. 19 is a circuit diagram illustrating a configuration example of a pixel 10230 in a mode of the present technique.

FIG. 20 is a block diagram depicting an example of schematic configuration of a vehicle control system.

FIG. 21 is a diagram of assistance in explaining an example of installation positions of an outside-vehicle information detecting section and an imaging section.

### MODES FOR CARRYING OUT THE INVENTION

Embodiments of a light receiving device and an electronic apparatus are hereinafter described with reference to the drawings. In the following, main constituent parts of the imaging apparatus and the electronic apparatus are mainly described, but the light receiving device and the electronic apparatus may have constituent parts or functions that are not illustrated or described. The following description does not exclude the constituent parts or functions that are not illustrated or described.

### First Embodiment

### <Configuration Example of Light Receiving Device>

FIG. 1 is a block diagram illustrating a schematic configuration example of a light receiving device to which the present technique is applied. A light receiving device 1 illustrated in FIG. 1 is, for example, a device that outputs ranging information by a ToF (Time of Flight) method.

The light receiving device 1 receives light (reflected light) being light (irradiation light) that has been applied from a predetermined light source and is then hit and reflected by an object, and outputs a depth image in which information regarding a distance to the object is stored as a depth value. It is to be noted that the irradiation light applied from the light source is, for example, infrared light in a wavelength range of 780 nm to 1,000 nm, and is, for example, pulsed light in which ON and OFF are repeated in a predetermined period.

The light receiving device 1 includes a pixel array section 21 formed on a semiconductor substrate (not illustrated), and a peripheral circuit section integrated on the same semiconductor substrate as the pixel array section 21. The peripheral circuit section includes, for example, a vertical driver 22, a column processor 23, a horizontal driver 24, and a system controller 25.

The light receiving device 1 further has provided thereto a signal processor 26 and a data storage 27. It is to be noted that the signal processor 26 and the data storage 27 may be mounted on the same substrate as the light receiving device 1, or may be disposed on a substrate in a module different from the light receiving device 1.

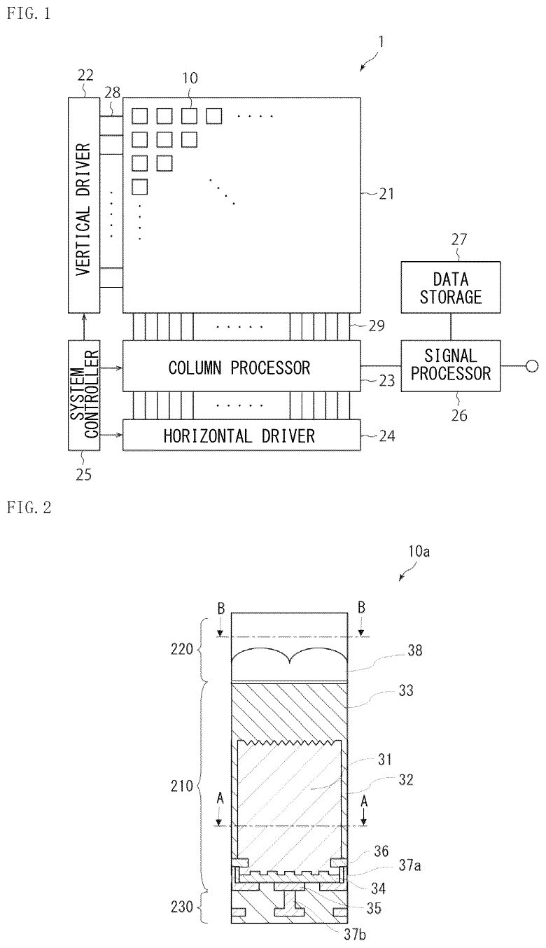

The pixel array section 21 has a configuration in which pixels 10 are two-dimensionally disposed in a matrix pattern in a row direction and a column direction. Each of the pixels 10 generates charges corresponding to the received light amount and outputs a signal corresponding to the charges. That is, the pixel array section 21 includes a plurality of pixels 10 each configured to perform photoelectric conversion of incident light and output a signal corresponding to charges obtained as a result of the photoelectric conversion. Details of the pixel 10 are described later with reference to FIG. 2 and the subsequent figures.

Here, the row direction refers to an array direction of the pixels 10 in a horizontal direction, and the column direction refers to an array direction of the pixels 10 in a vertical direction. The row direction is a lateral direction in the figure, and the column direction is a longitudinal direction in the figure.

In the pixel array section 21, for the matrix-pattern pixel array, a pixel drive line 28 is wired along the row direction for each pixel row, and two vertical signal lines 29 are wired along the column direction for each pixel column. For example, the pixel drive line 28 transmits a drive signal for performing drive at the time of reading out a signal from the pixel 10. It is to be noted that FIG. 1 illustrates the pixel drive line 28 as one wiring, but the number of wirings is not limited to one. One end of the pixel drive line 28 is coupled to an output end corresponding to each row of the vertical driver 22.

The vertical driver 22 includes, for example, a shift register or an address decoder, and drives the pixels 10 of the pixel array section 21 all at the same time or in a unit of rows, for example. That is, the vertical driver 22 forms a driver that controls the operation of each pixel 10 of the pixel array section 21, together with the system controller 25 that controls the vertical driver 22.

A detection signal output from each pixel 10 in a pixel row in accordance with the drive control performed by the vertical driver 22 is input to the column processor 23 through the vertical signal line 29. The column processor 23 performs predetermined signal processing on the detection signal output from each pixel 10 through the vertical signal line 29, and temporarily stores the detection signal subjected to the signal processing. Specifically, the column processor 23 performs noise removal processing, AD (Analog to Digital) conversion processing, or other types of processing as the signal processing.

The horizontal driver 24 includes, for example, a shift register or an address decoder, and selects a unit circuit corresponding to a pixel column of the column processor 23 in order. With this selection scanning performed by the horizontal driver 24, the detection signal subjected to signal processing for each unit circuit in the column processor 23 is output in order.

The system controller 25 includes, for example, a timing generator that generates various timing signals, and performs drive control of, for example, the vertical driver 22, the column processor 23, and the horizontal driver 24 on the basis of the various timing signals generated by this timing generator.

The signal processor 26 at least has an arithmetic processing function, and performs various types of signal processing such as arithmetic processing on the basis of the detection signal output from the column processor 23. For the signal processing in the signal processor 26, the data storage 27 temporarily stores data required for this processing.

The light receiving device 1 configured as described above outputs a depth image in which information regarding a distance to an object is stored as a depth value in a pixel value. For example, it is possible to mount the light receiving device 1 on an electronic apparatus such as an on-vehicle system that is mounted on a vehicle and measures a distance to an object present outside of the vehicle, or an apparatus for gesture recognition that measures a distance to an object such as a hand of a user to recognize the gesture of the user on the basis of its measurement result.

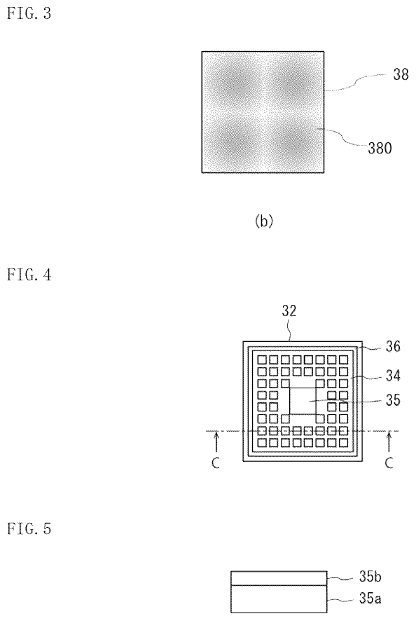

FIG. 2 is a diagram illustrating a configuration example of a pixel 10a provided in the light receiving device to which the present technique is applied. As illustrated in FIG. 2, the pixel 10a is, for example, an avalanche photodiode (APD). FIG. 3 is a BB cross-sectional diagram of FIG. 2, and FIG. 4 is an AA cross-sectional diagram of FIG. 2. Further, FIG. 2 is a CC cross-sectional diagram of FIG. 4.

In this embodiment, the APD is described as an example. The APD includes a Geiger mode for operation at a bias voltage higher than the breakdown voltage, and a linear mode for operation at a slightly high bias voltage near the breakdown voltage. The avalanche photodiode in the Geiger mode is also called “single-photon avalanche diode (SPAD).” The SPAD is a device that makes it possible to detect one photon for each pixel by multiplying carriers generated through photoelectric conversion, in a high-electric-field PN junction region (multiplication region section 35 to be described later) provided for each pixel. This embodiment is applied to, for example, the SPAD among the APDs. It is to be noted that the light receiving device in this embodiment may be applied to an image sensor for imaging or applied to a ranging sensor.

As illustrated in FIG. 2, the pixel 10a is configured by stacking an on-chip lens layer 220 on a light receiving surface side of a sensor substrate 210, and stacking a wiring layer 230 on a circuit surface side facing opposite to this light receiving surface. Further, the wiring layer 230 includes the multiplication region section 35 that multiplies carriers generated through photoelectric conversion, in a high-electric-field PN junction region provided for each pixel. The pixel 10a has a configuration in which the present technique is applied to, for example, a so-called back-illuminated type image sensor in which a circuit board (not illustrated) is stacked via the wiring layer 230 on a front surface side in a process of manufacturing a silicon substrate and light is illuminated on a back surface side. As a matter of course, the present technique may be applied to a front-illuminated type image sensor. It is to be noted that the light receiving device in this embodiment may be applied to an image sensor for imaging, or may be applied to a ranging sensor for ranging.

That is, this pixel 10a includes a well layer 31, a DTI (Deep Trench Isolation) 32, a reflection suppressor 33, a transmission suppressor 34, the multiplication region section 35, an anode 36, contacts 37a and 37b, and an optical member 38. In the sensor substrate 210, the DTI (Deep Trench Isolation) 32 being an element isolation structure that isolates adjacent pixels 10a from each other is formed so as to surround the semiconductor layer (well layer) 31 in which a photoelectric converter (photoelectric conversion device) that receives light in a predetermined wavelength range to perform photoelectric conversion is formed. For example, the DTI 32 is configured by embedding an insulator (for example, SiO₂) in a groove portion formed by digging the well layer 31 from the light receiving surface side.

The reflection suppressor 33 suppresses reflection of light entering the well layer 31 on a light receiving surface of the well layer 31. This reflection suppressor 33 includes, for example, an uneven structure formed by providing, at predetermined intervals, a plurality of quadrangular pyramid shapes or inverted quadrangular pyramid shapes including slopes having an inclination angle according to a plane index of a crystal plane of a single crystal silicon wafer that configures the well layer 31. More specifically, the reflection suppressor 33 includes an uneven structure in which the plane index of the crystal plane of the single crystal silicon wafer is 110 or 111, and an interval between adjacent vertices of the plurality of quadrangular pyramid shapes or inverted quadrangular pyramid shapes is, for example, 200 nm or more and 1,000 nm or less. It is to be noted that the pixel 10a according to this embodiment includes the reflection suppressor 33, but the pixel 10a is not limited thereto. For example, a pixel 10a including no reflection suppressor 33 may be provided.

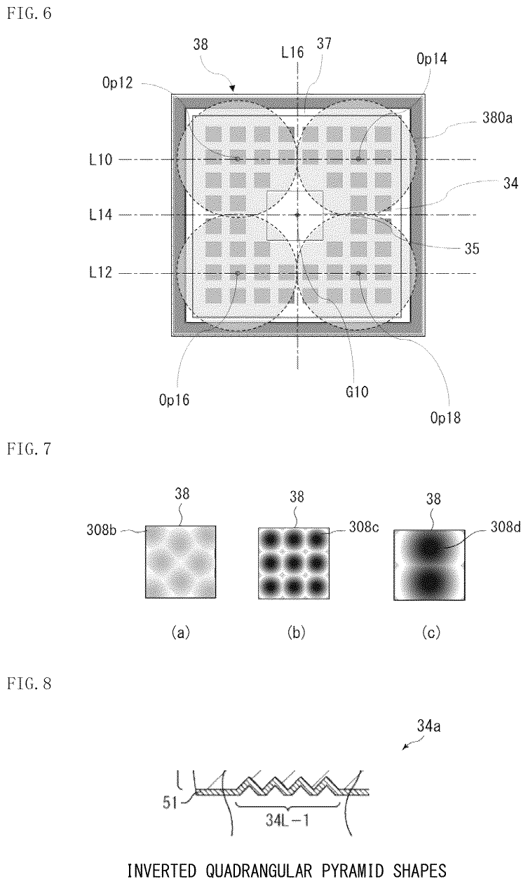

As illustrated in FIG. 2 and FIG. 3, the on-chip lens layer 220 includes the optical member 38 that condenses, for each pixel 10a, the light applied to the sensor substrate 210. Further, the on-chip lens layer 220 is stacked, for example, on a flat surface that has been flattened by an insulator in a process of embedding the insulator into the DTI 32 from the light receiving surface side of the well layer 31. The optical member 38 is a multifocal lens. This optical member 38 includes, for example, a plurality of on-chip lenses 380. The optical member 38 has a plurality of optical axes having incident-side vertex portions of the plurality of on-chip lenses 380 as base points, and zero-order light that passes through the plurality of optical axes enters the transmission suppressor 34. It is to be noted that details of the optical member 38 are described later with reference to FIG. 6 and FIG. 7.

As illustrated in FIG. 4, the transmission suppressor 34 is configured so as to surround the multiplication region section 35. That is, in the pixel 10a, the transmission suppressor 34 that suppresses transmission through the well layer 31 of light that has entered the well layer 31 is formed on a circuit surface of the well layer 31. This transmission suppressor 34 includes, for example, an uneven structure formed by digging, at predetermined intervals, a plurality of STIs (Shallow Trench Isolations) being shallow trenches that become recessed shapes with respect to the circuit surface of the well layer 31. That is, the transmission suppressor 34 is formed in a process similar to a process of forming the trenches of the DTI 32, but is formed to be shallower than the depth of the trenches of the DTI 32. For example, the transmission suppressor 34 includes an uneven structure in which trenches are dug to have a depth of 100 nm or more and an interval between adjacent trenches is 100 nm or more and 1,000 nm or less.

The multiplication region section 35 is coupled to wiring of the wiring layer 230 via the contact 37a. Details of the multiplication region section 35 are described later with reference to FIG. 5.

Referring back to FIG. 2, the anode 36 is coupled to the wiring of the wiring layer 230 via the contact 37b. The wiring layer 230 is stacked on the circuit surface of the well layer 31, and has a configuration in which a plurality of multilayer wirings insulated from each other by an interlayer insulating film is formed. As described above, the pixel 10a has a structure in which the reflection suppressor 33 is provided on the light receiving surface of the well layer 31 and the transmission suppressor 34 is provided on the circuit surface of the well layer 31, and the transmission suppressor 34 includes an uneven structure including a plurality of shallow trenches.

FIG. 5 is a side diagram of the multiplication region section 35. As illustrated in FIG. 5, the multiplication region section 35 includes an n-type semiconductor region 35a having a conductive type of, for example, n type (first conductive type) and a p-type semiconductor region 35b having a conductive type of, for example, p type (second conductive type). The n-type semiconductor region 35a is disposed on the wiring layer 230 side, and the p-type semiconductor region 35b is disposed above the n-type semiconductor region 35a, that is, on the on-chip lens layer 220 side. The multiplication region section 35 is formed in the well layer 31. The well layer 31 may be a semiconductor region having a conductivity type of n type, or may be a semiconductor region having a conductivity type of p type. Further, the well layer 31 is preferably, for example, an n-type or p-type semiconductor region having a low concentration in the order of 1E14 or less. This allows the well layer 31 to be easily depleted and makes it possible to improve the PDE.

The n-type semiconductor region 35a is, for example, a semiconductor region that includes Si (silicon), has a high impurity concentration, and has a conductivity type of n type. The p-type semiconductor region 35b is a semiconductor region that has a high impurity concentration and has a conductivity type of p type. The p-type semiconductor region 35b configures a pn junction at an interface with the n-type semiconductor region 35a. The p-type semiconductor region 35b includes a multiplication region that avalanche-multiplies the carriers generated by incident light to be detected. The p-type semiconductor region 35b is preferably depleted, and this makes it possible to improve the PDE.

FIG. 6 is a schematic plan diagram obtained by schematically overlapping optical axes OP12 to OP18 of the optical member 38 and the transmission suppressor 34. The optical member 38 includes four on-chip lenses 380a. A center portion of the multiplication region section 35 is represented by G10, and the optical axes of the four on-chip lenses 380a are respectively represented by OP12 to OP18. In this case, the optical axes OP12 to OP18 respectively correspond to optical paths on which zero-order light beams that have respectively passed through the four on-chip lenses 380a travel. Further, a line segment connecting the optical axes OP12 and OP14 with each other is represented by L10. A line segment connecting the optical axes OP12 and OP14 with each other is represented by L12. A line segment passing through the center portion G10 and being parallel to the line segments L10 and L12 is represented by L14. The on-chip lens 380a includes a transparent organic material or an inorganic material (SiN, Si, or αSi).

As illustrated in FIG. 6, the optical axes OP12 to OP18 vertically pass through a bottom surface (horizontal surface) of the transmission suppressor 34 excluding the multiplication region section 35. In this manner, transmission through the well layer 31 of, among incident light beams passing via the optical member 38, a zero-order light component traveling straight through the well layer 31 is suppressed by the uneven structure of the transmission suppressor 34.

Further, the optical axes OP12 to OP18 have equal distances from the center portion G10. Moreover, a line segment connecting the center portion G10 and each of the optical axes OP12 to OP18 with each other has rotational symmetry with respect to the center portion G10. That is, the optical axes OP12 and OP14 and the optical axes OP16 and OP18 have line symmetry with respect to the line segment L14, and the optical axes OP12 and OP16 and the optical axes OP16 and OP18 have line symmetry with respect to a line segment L16 passing through the center portion G10 and being orthogonal to the line segment L14. As described above, the optical axes OP12 to OP18 are provided symmetrically with respect to the center portion G10. In this manner, electric potentials made in the well layer 31 are caused to have symmetry with respect to the center portion G10, and it is thus possible to collect the carriers generated through photoelectric conversion of light that has passed through each of the four on-chip lenses 380a to the center portion G10 of the multiplication region section 35 at an equal probability. In this manner, a measurement error is suppressed even when the multifocal optical member 38 is disposed.

Referring back to FIG. 2, incident light beams entering the well layer 31 are diffracted by the reflection suppressor 33, and transmission through the well layer 31 of, among those incident light beams, a zero-order light component traveling straight through the well layer 31 is suppressed by the uneven structure of the transmission suppressor 34. Further, among those incident light beams, a first-order light component diffracted by the reflection suppressor 33 is reflected by the DTI 32, and is then also reflected by the transmission suppressor 34 of the well layer 31. This allows the pixel 10a to confine the incident light beams that have entered the well layer 31 by a combination of the DTI 32 and the transmission suppressor 34, that is, allows the pixel 10a to suppress transmission of the incident light beams to the outside of the well layer 31. Accordingly, it is possible for the pixel 10a to improve its light absorption efficiency particularly from red wavelengths to near infrared rays even when the well layer 31 has a limited thickness. As a result, it is possible for the pixel 10a to extremely improve its sensitivity to those wavelength ranges, its quantum effect, or the like, and it is thus possible to improve the sensor sensitivity. Further, each of the optical axes OP12 to OP18 is disposed symmetrically from the center portion G10, and it is thus possible to collect the carriers generated by light that has passed through the optical member 38 symmetrically with respect to the center portion G10.

In a case where there is no symmetry in density of carriers generated by the light that has passed through the optical member 38, a difference is caused in time of arriving to the multiplication region section 35, depending on the region in which the carriers are generated. As understood from this, the measurement accuracy is reduced as the difference in arrival time is increased. In contrast, in the pixel 10a according to this embodiment, as described above, the multiplication region section 35 is disposed at the center portion G10 of the pixel 10a, and each of the optical axes OP12 to OP18 is disposed symmetrically from the center portion G10. In this manner, the carriers generated by the light that has passed through the optical member 38 are symmetrically collected to the center portion G10. Thus, while reduction of the measurement accuracy is suppressed, the entry of the zero-order light to the multiplication region section 35 is suppressed.

FIG. 7 are diagrams illustrating other configuration examples of the multifocal optical member 38. Each of the optical axes of the optical member 38 passes through the transmission suppressor 34. Thus, transmission through the well layer 31 of, among the incident light beams, the zero-order light component traveling straight through the well layer 31 is suppressed by the uneven structure of the transmission suppressor 34. FIG. 7(a) is an example in which the optical member 38 includes eight on-chip lenses 380b. FIG. 7(b) is an example in which the optical member 38 includes nine on-chip lenses 380c. FIG. 7(c) is an example in which the optical member 38 includes nine on-chip lenses 380d. The optical axes of the respective on-chip lenses are rotationally symmetric with respect to the center portion G10 of the multiplication region section 35. This makes it possible to collect the carriers generated by the light that has passed through the optical member 38 rotational-symmetrically to the center portion G10.

As described above, the optical axes of the multifocal optical member 38 according to this embodiment are formed so as to maintain symmetry such as rotational symmetry or line symmetry with respect to the center portion G10. This causes electric potentials to have symmetry, or causes an electric potential to be further generated for compensating for the symmetry of the density of the carriers generated through carrier photoelectric conversion. In this manner, reduction of the measurement accuracy is suppressed.

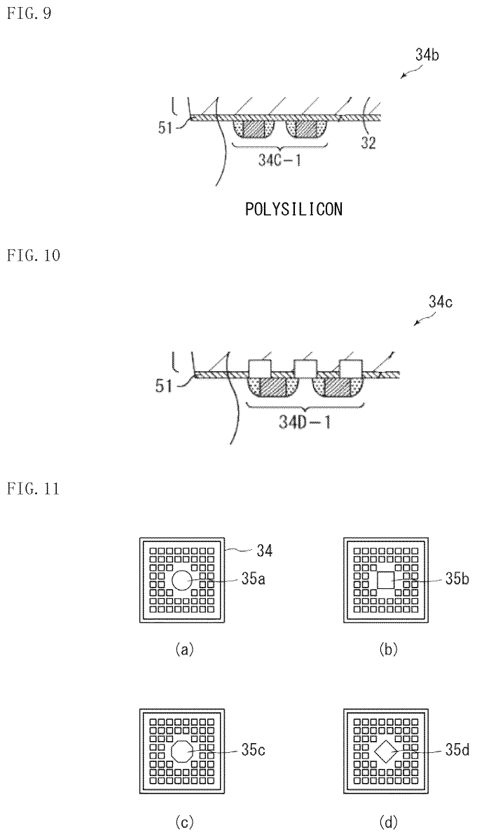

Here, other structure examples of the transmission suppressor 34 are described with reference to FIG. 8 to FIG. 10. FIG. 8 is a diagram illustrating a structure example of a transmission suppressor 34a. As illustrated in FIG. 8, the transmission suppressor 34a includes an optically-thin insulating film 51 formed on the circuit surface of the well layer 31. The transmission suppressor 34a includes, for example, similarly to the reflection suppressor 33, an uneven structure 34L-1 formed by providing, at predetermined intervals, a plurality of quadrangular pyramid shapes or inverted quadrangular pyramid shapes including slopes having an inclination angle according to a plane index of a crystal plane of a single crystal silicon wafer that configures the well layer 31. More specifically, the transmission suppressor 34a includes an uneven structure in which the plane index of the crystal plane of the single crystal silicon wafer is 110 or 111, and an interval between adjacent vertices of the plurality of quadrangular pyramid shapes or inverted quadrangular pyramid shapes is, for example, 200 nm or more and 1,000 nm or less.

FIG. 9 is a diagram illustrating a structure example of a transmission suppressor 34b obtained by a dummy electrode. As illustrated in FIG. 9, the transmission suppressor 34b includes, for example, an uneven structure formed by disposing, at predetermined intervals, a plurality of so-called dummy electrodes 34C-1 that becomes protruding shapes of the well layer 31. For example, the dummy electrode included in the transmission suppressor 34b can be formed of polysilicon similarly to a gate electrode, and is stacked on the circuit surface of the well layer 31 through intermediation of the insulating film 51. Further, this dummy electrode is electrically floated or fixed at a ground potential. More specifically, the transmission suppressor 34c includes an uneven structure in which the dummy electrodes are formed to have a height of 100 nm or more and an interval between adjacent dummy electrodes is 100 nm or more and 1,000 nm or less.

FIG. 10 is a diagram illustrating another structure example of the transmission suppressor 34. As illustrated in FIG. 10, a transmission suppressor 34c includes, for example, a combination of an uneven structure formed by digging, at predetermined intervals, a plurality of shallow trenches that becomes recessed shapes with respect to the circuit surface of the well layer 31 and an uneven structure formed by disposing, at predetermined intervals, a plurality of dummy electrodes 34D-1 that becomes protruding shapes with respect to the circuit surface of the well layer 31. That is, the transmission suppressor 34c includes a combination of the transmission suppressor 34 illustrated in FIG. 2 and the transmission suppressor 34b illustrated in FIG. 9. More specifically, the transmission suppressor 34c includes an uneven structure including trenches that are dug to have a depth of 100 nm or more and have an interval between adjacent ones of 100 nm or more and 1,000 nm or less and dummy electrodes 34D-1 that are formed to have a height of 100 nm or more and have an interval between adjacent ones of 100 nm or more and 1,000 nm or less. Further, this dummy electrode 34D-1 is stacked on the circuit surface of the semiconductor layer 310 through intermediation of the insulating film 51, and is electrically floated or fixed at a ground potential.

FIG. 11 are diagrams illustrating planar shape examples of the multiplication region section 35. As illustrated in FIG. 11, the planar shape of the multiplication region section 35 can be a circle as illustrated in FIG. 11(a), a square as illustrated in FIG. 11(b), an octagon as illustrated in FIG. 11(c), a diamond as illustrated in FIG. 11(d), or other shapes. As described above, the planar shape of the multiplication region section 35 can be configured so as to be more appropriate for, for example, an optical characteristic of the optical member 38, a shape characteristic of the transmission suppressor 34, and an electric potential. It is to be noted that the planar shape of the multiplication region section 35 is not limited to those shapes, and the planar shape of the multiplication region section 35 can be configured so as to be more appropriate for the optical characteristic, the shape characteristic of the transmission suppressor 34, and the electric potential.

As described above, according to this embodiment, the transmission suppressor 34 including the uneven structure is configured to surround the multiplication region section 35. That is, in the pixel 10a, the transmission suppressor 34 that suppresses transmission through the well layer 31 of light that has entered the well layer 31 is formed on the wiring-side surface of the well layer 31, the multifocal optical member 38 is formed on the incident-side surface of the well layer 31, and each of the plurality of optical axes OP12 to OP18 is formed so as to pass through the transmission suppressor 34. In this manner, transmission through the well layer 31 of, among the incident light beams passing via the optical member 38, the zero-order light component traveling straight through the well layer 31 is suppressed by the uneven structure of the transmission suppressor 34. Accordingly, it is possible for the pixel 10a to improve its light absorption efficiency particularly from red wavelengths to near infrared rays even when the well layer 31 has a limited thickness. As a result, it is possible for the pixel 10a to extremely improve its sensitivity to those wavelength ranges, its quantum effect, or the like, and it is thus possible to improve the sensor sensitivity. As described above, the carriers are generated symmetrically with respect to the center portion G10 by light that has passed through the optical member 38. Thus, while reduction of the measurement accuracy is suppressed, the entry of the zero-order light to the multiplication region section 35 is suppressed.

### Second Embodiment

A pixel 10b of an optical device according to a second embodiment is different from the pixel 10a of the optical device according to the first embodiment in that the pixels 10b are configured as a CMOS image sensor. The difference from the optical device according to the first embodiment is hereinafter described.

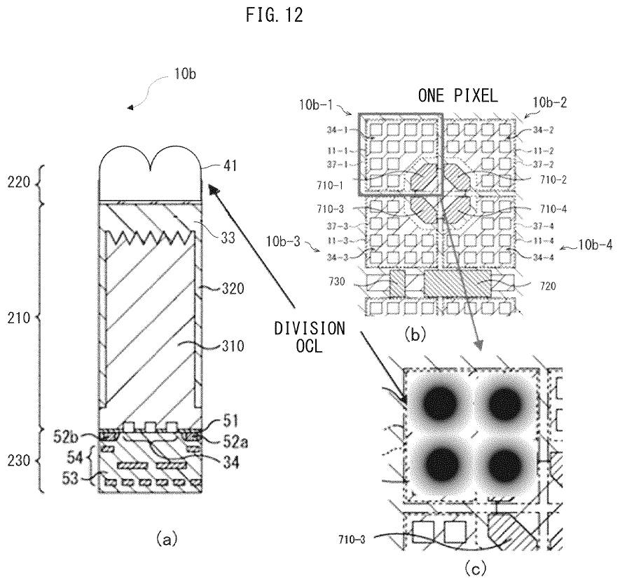

FIG. 12 are diagrams illustrating a configuration example of the pixel 10b according to the second embodiment. FIG. 12(a) illustrates a cross-sectional configuration example of the pixel 10b, FIG. 12(b) illustrates an example of a planar layout of the optical device including the pixel 10b, and FIG. 12(c) illustrates an example of an optical member 41 of the pixel 10b.

As illustrated in FIG. 12(a), the pixel 10b includes an on-chip lens layer 220 stacked on a light receiving surface side of a sensor substrate 210, and a wiring layer 230 stacked on a circuit surface side facing opposite to this light receiving surface. In the sensor substrate 210, a DTI (Deep Trench Isolation) 320 being an element isolation structure that isolates adjacent pixels 10b from each other is formed so as to surround a semiconductor layer 310 in which a photoelectric converter that receives light in a predetermined wavelength range to perform photoelectric conversion is formed. For example, the DTI 320 is configured by embedding an insulator (for example, SiO₂) in a groove portion formed by digging the semiconductor layer 310 from the light receiving surface side. Further, in the example illustrated in FIG. 12(a), the DTI 320 is formed to have a depth that provides a state in which the semiconductor layer 310 is connected between adjacent pixels 10b on the circuit surface side of the semiconductor layer 310.

Further, the pixel 10b includes a reflection suppressor 33 formed on a light receiving surface of the semiconductor layer 310 so as to suppress reflection of light entering the semiconductor layer 310. In addition, the pixel 10b includes a transmission suppressor 34 formed on a circuit surface of the semiconductor layer 310 so as to suppress transmission through the semiconductor layer 310 of light that has entered the semiconductor layer 310.

The on-chip lens layer 220 includes the optical member 41 that condenses, for each pixel 10b, light applied to the sensor substrate 210. As illustrated in FIG. 12(c), the optical member 41 is a multifocal lens, and includes a plurality of on-chip lenses. An optical axis of each of the on-chip lenses is caused to pass through the transmission suppressor 34. In this manner, for example, it is possible to cause the optical axis of each of the on-chip lenses to pass through the transmission suppressor 34 excluding a region of a transfer transistor 710-1. This suppresses the entry of zero-order light that has entered the optical member 41 to the region of the transfer transistor 710-1.

The wiring layer 230 has a configuration in which an optically-thin insulating film 51 is formed on the circuit surface of the semiconductor layer 310, gate electrodes 52a and 52b are stacked through intermediation of the insulating film 51, and a plurality of multilayer wirings 54 insulated from each other by an interlayer insulating film 53 is formed.

As described above, the pixel 10b has a structure in which the reflection suppressor 33 is provided on the light receiving surface of the semiconductor layer 310 and the transmission suppressor 34 is provided on the circuit surface of the semiconductor layer 310, and the transmission suppressor 34 includes an uneven structure including a plurality of shallow trenches. This allows the pixel 10b to confine the incident light that has entered the semiconductor layer 310 by a combination of the DTI 320 and the transmission suppressor 34, that is, allows the pixel 10b to suppress transmission of the incident light to the outside of the semiconductor layer 310.

As illustrated in FIG. 12(b), the optical device can adopt a pixel sharing structure in which a predetermined number of pixels 10b share a transistor. FIG. 12(b) is a schematic diagram of a pixel sharing structure including three pixels 10b-1 to 10b-4 arranged in a 2×2 shape.

As illustrated in FIG. 12(b), in the pixel sharing structure, transfer transistors 710-1 to 710-4 are respectively provided for the pixels 10b-1 to 10b-4. Further, in the pixel sharing structure, one amplification transistor 720, one selection transistor 730, and one reset transistor 74 to be shared are provided for the pixels 10b-1 to 10b-4. In addition, a transistor to be used for drive of those pixels 10b-1 to 10b-4 is disposed on the circuit surface side of the semiconductor layer 310.

Accordingly, transmission suppressors 34-1 to 34-4 provided on the circuit surface of the semiconductor layer 310 are respectively formed in effective pixel regions 37-1 to 37-4 as illustrated, for the respective pixels 10b-1 to 10b-4, when the optical device is viewed in plan view from the circuit surface side. In this case, the effective pixel regions 37-1 to 37-4 are regions obtained by removing, from respective regions of the pixels 10b-1 to 10b-4, a range in which the transfer transistors 710-1 to 710-4, the amplification transistor 720, and the selection transistor 730 are disposed. That is, the zero-order light of the optical member 41 is caused to pass through the effective pixel regions 37-1 to 37-4. Thus, while reduction of a photoelectric conversion efficiency of the pixels 10b-1 to 10b-4 is suppressed, transmission of the zero-order light through a range excluding the transmission suppressor 34 is suppressed.

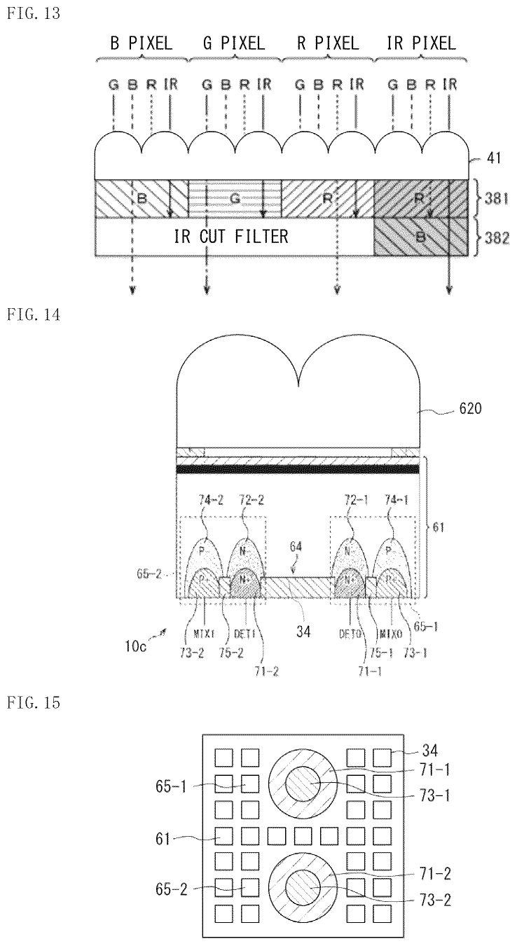

FIG. 13 is a cross-sectional diagram illustrating an example of a color filter layer inserted between the reflection suppressor 33 and the optical member 41 when the pixels 10b-1 to 10b-4 are configured as an RGB-IR imaging sensor.

In FIG. 13, the pixels 10b-1 to 10b-4 are schematically arranged in order from the left to the right. That is, the pixels 10b-1 to 10b-4 respectively correspond to a B pixel, a G pixel, an R pixel, and an IR pixel.

A first color filter layer 381 and a second color filter layer 382 are inserted between the reflection suppressor 33 and the optical member 41. In an IR pixel, an R filter that transmits light of R is disposed in the first color filter layer 381, and a B filter that transmits light of B is disposed in the second color filter layer 382. This causes light in wavelengths other than wavelengths of from B to R to pass, and hence light of IR passes through the first color filter layer 381 and the second color filter layer 382 to enter the semiconductor layer 310 via the reflection suppressor 33.

As described above, according to this embodiment, the transmission suppressor 34 including the uneven structure is formed on the wiring-side surface of the semiconductor layer 310, and the multifocal optical member 41 is formed on the incident-side surface of the semiconductor layer 310. Further, each of the plurality of optical axes of the optical member 41 is formed to pass through the transmission suppressor 34. In this manner, transmission through the semiconductor layer 310 of, among the incident light beams passing via the optical member 41, the zero-order light component traveling straight through the semiconductor layer 310 is suppressed by the uneven structure of the transmission suppressor 34. Further, the multifocal optical member 41 allows the zero-order light component traveling straight through the semiconductor layer 310 to be uniformly dispersed with respect to the transmission suppressor 34. Thus, it is possible for the pixel 10b to improve its light absorption efficiency even when the semiconductor layer 310 has a limited thickness, while reduction of a photoelectric conversion efficiency is suppressed.

### Third Embodiment

A pixel 10c of an optical device according to a third embodiment is different from the pixel 10a of the optical device according to the first embodiment in that the pixels 10c are configured as a CAPD (Current Assisted Photonic Demodulator) sensor. The difference from the optical device according to the first embodiment is hereinafter described.

A ranging system utilizing an indirect ToF (Time of Flight) method has been known. It is necessary for such a ranging system to include a sensor that makes it possible to distribute signal charges to different regions at high speed. The signal charges are obtained by receiving light being active light that has been applied with use of a LED (Light Emitting Diode) or a laser at a certain phase and is then hit and reflected by an object. In view of the above, there has been proposed a technique of, for example, directly applying a voltage to a substrate of a sensor to generate a current in the substrate so as to allow high-speed modification of a wide range of region within the substrate. Such a sensor is also called “CAPD (Current Assisted Photonic Demodulator) sensor.”

FIG. 14 is a cross-sectional diagram of the pixel 10c according to the third embodiment. That is, the pixel 10c corresponds to one pixel in the CAPD sensor. FIG. 15 is a plan diagram illustrating a configuration example of a portion of a signal extractor of the pixel 10c.

This pixel 10c receives incident light from the outside, particularly infrared light and performs photoelectric conversion to output a signal corresponding to charges obtained as a result of the photoelectric conversion. The pixel 10c includes a substrate 61 (semiconductor layer) and an optical member 620. The substrate 61 is, for example, a silicon substrate, that is, a P-type semiconductor substrate including a P-type semiconductor region. The optical member 620 is formed on this substrate 61.

Inside of the substrate 61 on a side of a surface opposite to the incident surface, that is, in an inner portion of a lower surface in the figure, an oxide film 64, a signal extractor 65-1, and a signal extractor 65-2 are formed. The signal extractor 65-1 and the signal extractor 65-2 are called taps.

In this example, the oxide film 64 is formed in a center portion of the pixel 10c near a surface of the substrate 61 on a side opposite to the incident surface, and the signal extractor 65-1 and the signal extractor 65-2 are formed at both ends of the oxide film 64. Further, a transmission suppressor 34 is formed on the surface of the oxide film 64.

In this case, the signal extractor 65-1 includes an N+ semiconductor region 71-1 that is an N-type semiconductor region and an N− semiconductor region 72-1 having a donor impurity concentration lower than that of the N+ semiconductor region 71-1, and a P+ semiconductor region 73-1 that is a P-type semiconductor region and a P− semiconductor region 74-1 having an acceptor impurity concentration lower than that of the P+ semiconductor region 73-1. In this case, examples of the donor impurity include elements belonging to group V in the periodic table of elements such as phosphorus (P) or arsenic (As) with respect to Si, and examples of the acceptor impurity include elements belonging to group III in the periodic table of elements such as boron (B) with respect to Si. An element that becomes a doner impurity is referred to as “doner element,” and an element that becomes an acceptor impurity is referred to as “acceptor element.”

That is, the N+ semiconductor region 71-1 is formed at a position adjacent on the right side in the figure to the oxide film 64, in a surface inner portion of the surface of the substrate 61 on the side opposite to the incident surface. Further, the N− semiconductor region 72-1 is formed on the upper side in the figure of the N+ semiconductor region 71-1 so as to cover (surround) this N+ semiconductor region 71-1. Moreover, the P+ semiconductor region 73-1 is formed at a position adjacent on the right side in the figure to the N+ semiconductor region 71-1, in the surface inner portion of the surface of the substrate 61 on the side opposite to the incident surface. Further, the P− semiconductor region 74-1 is formed on the upper side in the figure of the P+ semiconductor region 73-1 so as to cover (surround) this P+ semiconductor region 73-1.

It is to be noted that, although not illustrated here, in more detail, when the substrate 61 is viewed from a direction vertical to the surface of the substrate 61, the N+ semiconductor region 71-1 and the N− semiconductor region 72-1 are formed so as to surround the P+ semiconductor region 73-1 and the P− semiconductor region 74-1 with the P+ semiconductor region 73-1 and the P− semiconductor region 74-1 serving as centers.

Similarly, the signal extractor 65-2 includes an N+ semiconductor region 71-2 that is an N-type semiconductor region and an N− semiconductor region 72-2 having a donor impurity concentration lower than that of the N+ semiconductor region 71-2, and a P+ semiconductor region 73-2 that is a P-type semiconductor region and a P− semiconductor region 74-2 having an acceptor impurity concentration lower than that of the P+ semiconductor region 73-2.

Further, as illustrated in FIG. 14 and FIG. 15, the transmission suppressor 34 is configured to surround the P− semiconductor region 74-2, the N− semiconductor region 72-2, the N− semiconductor region 72-1, and the P− semiconductor region 74-1.

The optical member 620 is a multifocal lens. The optical member 620 includes, for example, a plurality of on-chip lenses. The optical axes of the plurality of on-chip lenses are caused to pass through the transmission suppressor 34 excluding the P− semiconductor region 74-2, the N− semiconductor region 72-2, the N− semiconductor region 72-1, and the P− semiconductor region 74-1. In this case, similarly to FIG. 4 described above, it is possible to form the plurality of optical axes in the multifocal optical member 620 to maintain symmetry with respect to a midpoint between the N+ semiconductor region 71-1 and the N+ semiconductor region 71-2. In this manner, the carriers generated by light that has passed through the substrate 61 are symmetrically collected to the N+ semiconductor region 71-1 and the N+ semiconductor region 71-2 so that, while reduction of the measurement accuracy is suppressed, the entry of zero-order light to the P− semiconductor region 74-2, the N− semiconductor region 72-2, the N− semiconductor region 72-1, and the P− semiconductor region 74-1 is suppressed.

As described above, according to this embodiment, the transmission suppressor 34 is configured to surround the P− semiconductor region 74-2, the N− semiconductor region 72-2, the N− semiconductor region 72-1, and the P− semiconductor region 74-1. Further, in the pixel 10c, the multifocal optical member 620 is formed on the incident surface side of the substrate 61, and each of the plurality of optical axes is formed so as to pass through the transmission suppressor 34. In this manner, transmission through the substrate 61 of, among the incident light beams passing via the optical member 620, the zero-order light component traveling straight through the substrate 61 is suppressed by the uneven structure of the transmission suppressor 34. Accordingly, it is possible for the pixel 10c to improve its light absorption efficiency particularly from red wavelengths to near infrared rays even when the substrate 61 has a limited thickness. As a result, it is possible for the pixel 10c to extremely improve its sensitivity to those wavelength ranges, its quantum effect, or the like, and it is thus possible to improve the sensor sensitivity. Further, it is possible to form the plurality of optical axes in the multifocal optical member 620 so as to maintain symmetry with respect to the midpoint between the N+ semiconductor region 71-1 and the N+ semiconductor region 71-2. This allows the carriers generated by light that has passed through the substrate 61 to be collected symmetrically with respect to the signal extractor 65-1 and the signal extractor 65-2.

### Fourth Embodiment

A pixel 10c of an optical device according to a fourth embodiment is different from the pixel 10 of the optical device according to the first embodiment in that the pixels are configured as a gate indirect time-of-flight (Gate-iToF) sensor. The difference from the optical device according to the first embodiment is hereinafter described.

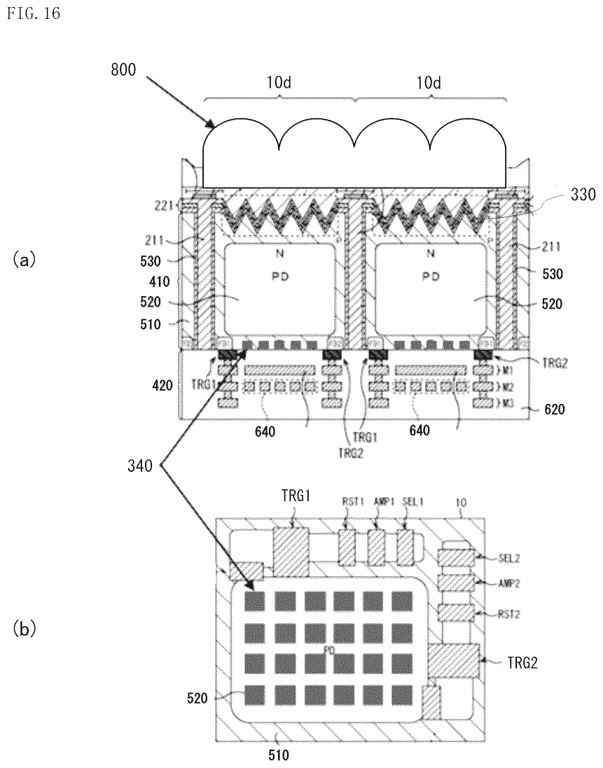

FIG. 16 are diagrams illustrating a configuration example of the pixel 10d according to the fourth embodiment. FIG. 16(a) is a cross-sectional diagram. FIG. 16(b) is a plan diagram. This pixel 10d is a pixel example of a Gate-iToF sensor. The light receiving device includes a semiconductor substrate (semiconductor layer) 410 and a multilayer wiring layer 420 formed on a surface side of the semiconductor substrate 410 (lower side in the figure).

The semiconductor substrate 410 includes, for example, silicon (Si), and is formed to have, for example, a thickness of 1 μm to 6 μm. In the semiconductor substrate 410, for example, in a P-type (first conductivity type) semiconductor region 510, an N-type (second conductivity type) semiconductor region 520 is formed in a unit of pixels so that a photodiode PD is formed in a unit of pixels. The P-type semiconductor region 510 provided on both front and back surfaces of the semiconductor substrate 410 also serves as a hole charge accumulating region that suppresses a dark current. A material that fills a trench (groove) dug from the back surface side as an inter-pixel isolator 211 may be, for example, a metal material such as tungsten (W), aluminum (Al), titanium (Ti), or titanium nitride (TiN).

As illustrated in FIG. 16(a), a transmission suppressor 340 is disposed at a boundary region between the semiconductor region 520 and the multilayer wiring layer 420. The transmission suppressor 340 has a configuration equivalent to that of the above-described transmission suppressor 34. As illustrated in FIG. 16(b), the transmission suppressor 340 is configured to cover the entire region of the surface of the photodiode PD on the multilayer wiring layer 420 side.

Further, as illustrated in FIG. 16(a), a photodiode (PD) upper region 330 positioned above the region in which the photodiode PD is formed has a moth-eye structure in which fine protrusions and recesses are formed. Further, an anti-reflection film formed above the photodiode (PD) upper region 330 of the semiconductor substrate 410 is also formed of a moth-eye structure so as to correspond to the moth-eye structure of the photodiode (PD) upper region 330 of the semiconductor substrate 410. The anti-reflection film is configured by stacking, similarly to the first configuration example, a hafnium oxide film 53, an aluminum oxide film 54, and a silicon oxide film 55.

As described above, with the PD upper region 330 of the semiconductor substrate 410 being formed of the moth-eye structure, it is possible to relax an abrupt change in refractive index at a substrate interface, and to reduce influence to be caused by reflection light. It is to be noted that the upper region 330 according to this embodiment corresponds to the reflection suppressor.

Further, as illustrated in FIG. 16(a), an optical member 800 is a multifocal lens. The optical member 800 includes, for example, a plurality of on-chip lenses. The optical axes of the plurality of on-chip lenses are caused to pass through the transmission suppressor 340. In this case, similarly to FIG. 4 described above, it is possible to form the plurality of optical axes in the multifocal optical member 800 so as to maintain symmetry with respect to a center point of the surface of the photodiode PD on the multilayer wiring layer 420 side. In this manner, the plurality of optical axes of the optical member 800 is formed equally while maintaining symmetry with respect to the center point in the photodiode PD. Thus, photoelectric conversion in the photodiode PD is more efficiently performed.

As described above, the transmission suppressor 340 blocks and reflects infrared light that has entered the semiconductor substrate 410 from a light incident surface via the on-chip lenses serving as the optical member 800 and has passed through the semiconductor substrate 410 without being photoelectrically converted in the semiconductor substrate 410. This prevents transmission to two metal films or the like below the transmission suppressor 340. This light blocking function makes it possible to prevent the infrared light that has passed through the semiconductor substrate 410 without being photoelectrically converted in the semiconductor substrate 410 from being scattered by the metal film to enter a close pixel. This makes it possible to prevent light from being erroneously detected in the close pixel.

Further, the transmission suppressor 340 also has a function of causing the infrared light that has entered the semiconductor substrate 410 from the light incident surface via the optical member 800 and has passed through the semiconductor substrate 410 without being photoelectrically converted in the semiconductor substrate 410 to be reflected by the transmission suppressor 340 to re-enter the semiconductor substrate 410.

This allows the pixel 10d to confine the incident light that has entered the semiconductor substrate 410 by a combination of the inter-pixel isolator 211 and the transmission suppressor 340, that is, allows the pixel 10d to suppress transmission to the outside of the semiconductor substrate 410. Accordingly, it is possible for the pixel 10d to improve its light absorption efficiency particularly from red wavelengths to near infrared rays even when the semiconductor substrate 410 has a limited thickness. As described above, this reflection function increases the amount of infrared light to be photoelectrically converted in the semiconductor substrate 410, and it is thus possible to improve the quantum efficiency (QE), that is, the sensitivity of the pixel 10d with respect to the infrared light. Moreover, the plurality of optical axes of the optical member 800 is formed equally while maintaining symmetry with respect to the center point in the photodiode PD, and hence the quantum efficiency (QE) can be further improved.

Meanwhile, on the surface side of the semiconductor substrate 410 on which the multilayer wiring layer 420 is formed, two transfer transistors TRG1 and TRG2 are formed with respect to one photodiode PD formed in each pixel 10d. Further, on the surface side of the semiconductor substrate 410, floating diffusion regions FD1 and FD2 serving as charge accumulators that temporarily store charges transferred from the photodiode PD are formed of high-concentration N-type semiconductor regions (N-type diffusion regions).

Further, as illustrated in FIG. 16(b), the photodiode PD is formed of the N-type semiconductor region 520 in a region at a middle portion of the rectangular pixel 10dd. On the outer side of the photodiode PD, along one predetermined side of four sides of the rectangular pixel 10d, a transfer transistor (not illustrated), a switching transistor FDG1, a reset transistor RST1, an amplification transistor AMP1, and a selection transistor SEL1 are disposed side by side in a linear manner, and, along another side of the four sides of the rectangular pixel 10d, a transfer transistor TRG2, a switching transistor (not illustrated), a reset transistor RST2, an amplification transistor AMP2, and a selection transistor SEL2 are disposed side by side in a linear manner.

Moreover, a charge discharge transistor (not illustrated) is disposed on a side different from the two sides of the pixel 10 on each of which the transfer transistor TRG, the switching transistor, the reset transistor RST, the amplification transistor AMP, and the selection transistor SEL are formed. It is to be noted that the layout of the pixel circuit illustrated in FIG. 16(b) is not limited to this example, and other layouts may be employed. As described above, according to this embodiment, the transmission suppressor 340 is configured to cover the entire region of the surface of the photodiode PD on the multilayer wiring layer 420 side at the boundary region between the conductor region 520 and the multilayer wiring layer 420. Further, the optical axes of the plurality of on-chip lenses included in the optical member 800 are caused to pass through the transmission suppressor 340. This allows the pixel 10d to confine the incident light that has entered the semiconductor substrate 410 by a combination of the inter-pixel isolator 211 and the transmission suppressor 340. Thus, it is possible for the pixel 10d to improve its light absorption efficiency particularly from red wavelengths to near infrared rays even when the semiconductor substrate 410 has a limited thickness. Moreover, the plurality of optical axes of the optical member 800 is equally formed while maintaining symmetry with respect to a predetermined center point in the photodiode PD, and hence it is possible to further improve the quantum efficiency (QE).

### <Configuration Example of Ranging Module>

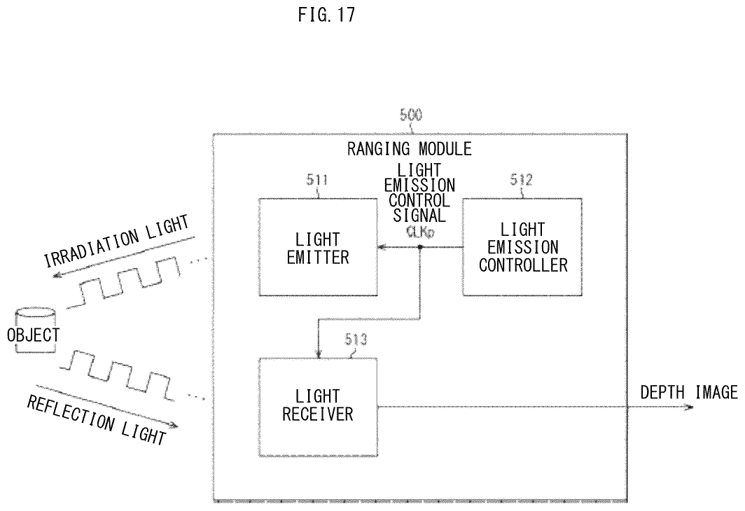

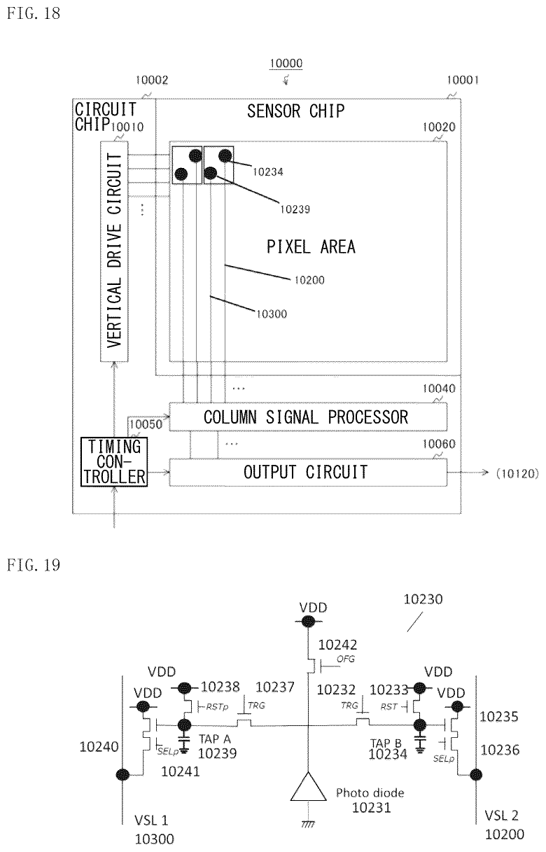

FIG. 17 is a block diagram illustrating a configuration example of a ranging module that outputs ranging information with use of the above-described light receiving device.

A ranging module (electronic apparatus) 500 includes a light emitter 511, a light emission controller 512, and a light receiver 513.

The light emitter 511 includes a light source that emits light of a predetermined wavelength, and emits irradiation light whose brightness periodically varies to irradiate an object with the irradiation light. For example, the light emitter 511 includes, as the light source, a light emitting diode that emits infrared light having a wavelength range of 780 nm to 1,000 nm, and generates irradiation light in synchronization with a light emission control signal CLKp being a square wave supplied from the light emission controller 512.

It is to be noted that the light emission control signal CLKp is not limited to a square wave as long as it is a periodic signal. For example, the light emission control signal CLKp may be a sine wave.

The light emission controller 512 supplies the light emission control signal CLKp to the light emitter 511 and the light receiver 513 to control irradiation timing of irradiation light. The frequency of this light emission control signal CLKp is, for example, 20 megahertz (MHz). It is to be noted that the frequency of the light emission control signal CLKp is not limited to 20 megahertz (MHz), and may be 5 megahertz (MHz) or other values.

The light receiver 513 receives reflected light reflected from the object, calculates, for each pixel, distance information in accordance with a light reception result, and generates and outputs a depth image in which a depth value corresponding to a distance to the object (subject) is stored as a pixel value.

As the light receiver 513, the light receiving device having the pixel structure of any one of the above-described first, third, and fourth embodiments is used. For example, the light receiving device serving as the light receiver 513 calculates, on the basis of the light emission control signal CLKp, the distance information for each pixel from a signal intensity corresponding to charges distributed to the floating diffusion region FD1 or FD2 of each pixel 10 of the pixel array section 21. It is to be noted that the number of taps of the pixel 10 may be the above-described four taps or others.

As described above, the light receiving device having the pixel structure of any one of the above-described first to sixth configuration examples can be incorporated as the light receiver 513 of the ranging module 500 that obtains and outputs the information regarding the distance to the subject by the indirect ToF method. This makes it possible to improve the ranging characteristic as the ranging module 500.

### <Configuration Example of Indirect Time-of-Flight Sensor>

FIG. 18 is a block illustrating of an example of an indirect time-of-flight sensor to which the present technique is applied.

FIG. 18 is a block diagram illustrating an example of an indirect time-of-flight sensor 10000 to which an embodiment of the present technique is applied. The indirect time-of-flight sensor 10000 includes a sensor chip 10001 and a circuit chip 10002 stacked on the sensor chip 10001.

A pixel area 10020 includes a plurality of pixels disposed in an array in a two-dimensional grid pattern on the sensor chip. The pixel area 10020 may have a matrix layout, and may further include a plurality of column signal lines. Each of the column signal lines is coupled to a corresponding one of the pixels. Further, a vertical drive circuit 10010, a column signal processing circuit 10040, a timing adjusting circuit 10050, and an output circuit 10060 are disposed in the circuit chip 10002.

The vertical drive circuit 10010 is configured to drive the pixel and output a pixel signal to the column signal processor 10040. The column signal processor 10040 executes analog-digital (AD) conversion processing on the pixel signal, and outputs the pixel signal subjected to the AD conversion processing to the output circuit. The output circuit 10060 executes, for example, CDS (Correlated Double Sampling) processing on data from the column signal processing circuit 10040, and outputs the data to a signal processing circuit 10120 on a downstream side.

The timing control circuit 10050 is configured to control the drive timing of each vertical drive circuit 10010. The column signal processor and the output circuit 10060 are synchronized with a vertical synchronization signal.

The pixel area 10020 has a plurality of pixels disposed in a two-dimensional grid pattern, and each of the pixels is configured to receive infrared light to perform photoelectric conversion into a pixel signal.

Further, for each column of pixels 10230, vertical signal lines VSL1 and VSL2 are wired in the vertical direction. When the total sum of the columns in the pixel region 10020 is represented by M (M is an integer), a total of 2×M vertical signal lines are wired. Each of the pixels includes two taps. The vertical signal line VSL1 is coupled to a tap A of the pixel 10230, and the vertical signal line VSL2 is coupled to a tap B of the pixel 10230. Further, the vertical signal line VSL1 transmits a pixel signal AINP1, and the vertical signal line VSL2 transmits a pixel signal AINP2.

The vertical drive circuit 210 selects and drives a row of a pixel block 221 in order, and simultaneously outputs the pixel signals AINP1 and AINP2 for each pixel block 221 in this row. In other words, the vertical drive circuit 210 simultaneously drives a 2k-th row and a (2k+1)th row of the pixels 230. It is to be noted that the vertical drive circuit 210 is an example of a drive circuit described in the scope of claims.

FIG. 19 is a circuit diagram illustrating a configuration example of the pixel 10230 in a mode of the present technique. This pixel 230 includes a photodiode 10231, two transfer transistors 10232 and 10237, two reset transistors 10233 and 10238, two taps (floating diffusion layers 10234 and 10239), two amplification transistors 10235 and 10239, and two selection transistors 10236 and 10241.

The photodiode 10231 performs photoelectric conversion of received light to generate charges. This photodiode 10231 is disposed on, when a surface of a semiconductor substrate on which a circuit is disposed serves as a front surface, a back surface with respect to the front surface. Such a solid-state imaging device is called “back-illuminated type solid-state imaging device.” It is to be noted that, in place of the back-illuminated type, it is possible to use a front-illuminated type configuration in which the photodiode 10231 is disposed on the front surface.

The transfer transistor 10232 sequentially transfers the charges to each of the tap A 10239 and the tap B 10234 from the photodiode 10231 in accordance with a transfer signal TRG from the vertical drive circuit 10010. Each of the tap A 10239 and the tap B 10234 accumulates the transferred charges to generate a voltage corresponding to the amount of the accumulated charges.

An overflow transistor 10242 is a transistor that sequentially discharges the charges of the photodiode 10231 to VDD, and has a function of resetting the photodiode.

The reset transistors 10233 and 10238 respectively extract charges from the tap A 10239 and the tap B 10234 in accordance with a reset signal RSTp from the vertical drive circuit 210, to thereby initialize the charge amount. The amplification transistors 10235 and 10240 respectively amplify the voltages of the tap A 10239 and the tap B 10234. The selection transistors 10236 and 10241 output, in accordance with a selection signal SELp from the vertical drive circuit 210, signals having amplified voltages to the column signal processor 10040 via two vertical signal lines (for example, VSL1 and VSL2) as pixel signals. VSL1 and VSL2 are coupled to input of one analog-digital converter XXX in the column signal processing circuit 10040.

It is to be noted that the circuit configuration of the pixel 230 is not limited to the configuration exemplified in FIG. 19 as long as the pixel 230 is possible to generate the pixel signal through photoelectric conversion.

### Application Example

A technique according to the present disclosure is applicable to various products. For example, the technique according to the present disclosure may be implemented as an apparatus to be mounted on a moving body of any type, such as an automobile, an electric vehicle, a hybrid electric vehicle, a motorcycle, a bicycle, a personal mobility, an airplane, a drone, a ship, a robot, construction equipment, or farm equipment (tractor).

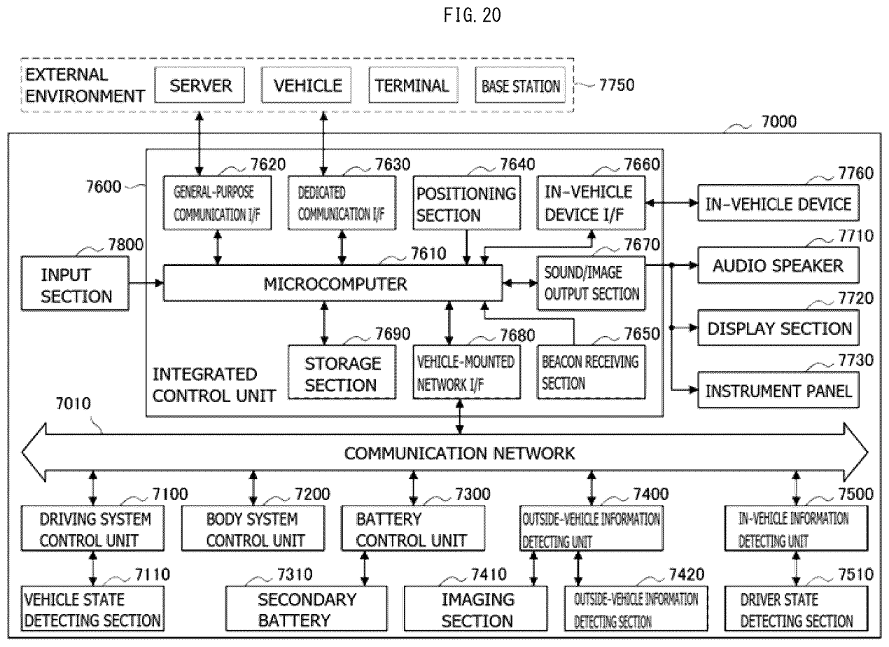

FIG. 20 is a block diagram depicting an example of schematic configuration of a vehicle control system 7000 as an example of a mobile body control system to which the technology according to an embodiment of the present disclosure can be applied. The vehicle control system 7000 includes a plurality of electronic control units connected to each other via a communication network 7010. In the example depicted in FIG. 20, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like inside and outside the vehicle by wire communication or radio communication. A functional configuration of the integrated control unit 7600 illustrated in FIG. 20 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

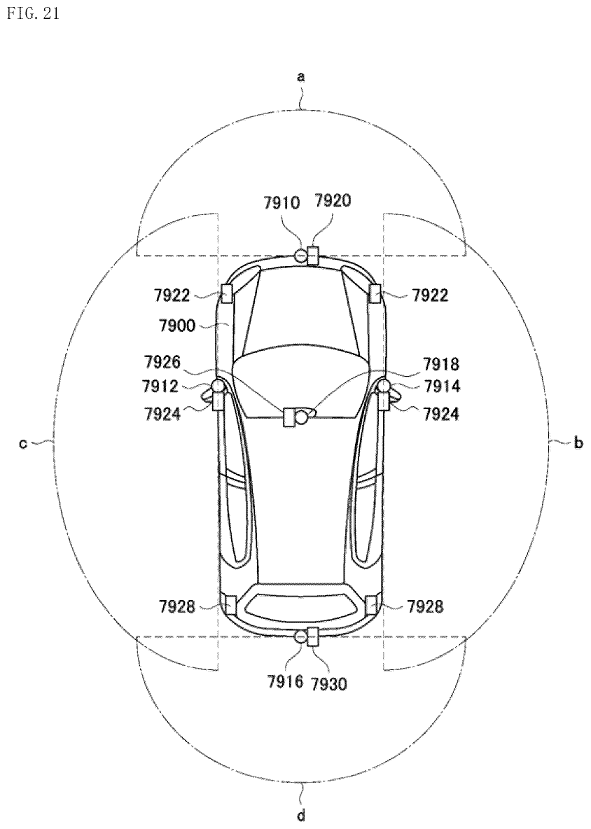

FIG. 21 depicts an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 21 depicts an example of photographing ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 20, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by different imaging sections 7410.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automated driving, which makes the vehicle to travel automatedly without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 20, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Incidentally, at least two control units connected to each other via the communication network 7010 in the example depicted in FIG. 20 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

In the vehicle control system 7000 described above, it is possible to apply the ranging module 500 according to this embodiment described with reference to FIG. 17 to the positioning section 7640 of the application example illustrated in FIG. 20.

It is to be noted that the present technique can take the following configurations.

(1)

A light receiving device including a plurality of pixels, each of the pixels including:
a multifocal optical member having a plurality of optical axes;
a semiconductor layer that receives light that is in a predetermined wavelength range and has passed through the optical member, to perform photoelectric conversion; and
a transmission suppressor that suppresses, on a first surface, on a side opposite to a light incident side, of the semiconductor layer, transmission of the light through the semiconductor layer.
   (2)

The light receiving device according to (1), in which
the optical member includes a plurality of on-chip lenses, and
zero-order light that passes through the plurality of optical axes having incident-side vertex portions of the plurality of on-chip lenses as base points enters the transmission suppressor.
   (3)

The light receiving device according to (1), in which
each of the pixels further includes a multiplication region section that multiplies carriers generated through the photoelectric conversion, and
on the first surface, the transmission suppressor is configured around the multiplication region section.
   (4)

The light receiving device according to (1), in which the transmission suppressor is configured in a region of the semiconductor layer in which a photoelectric conversion device is disposed, the region excluding a range in which a transistor to be used for drive of a corresponding one of the pixels is disposed.

(5)

The light receiving device according to (1), in which
the semiconductor layer is configured between the optical member and a wiring layer, and includes:
a first charge detector disposed around a first voltage applicator; and
a second charge detector disposed around a second voltage applicator, and
the transmission suppressor is configured in a region at least excluding the first charge detector and the second charge detector.
   (6)

The light receiving device according to (1), in which
the semiconductor layer includes a photodiode, and
the transmission suppressor is configured to overlap the photodiode in plan view.
   (7)

The light receiving device according to (1), in which the transmission suppressor includes an uneven structure formed on the first surface of the semiconductor layer.

(8)

The light receiving device according to (7), in which a pitch of the uneven structure is 200 nm or more and 1,000 nm or less.

(9)

The light receiving device according to (7), in which the uneven structure is formed by digging a plurality of trenches that becomes recessed shapes at predetermined intervals in the semiconductor layer.

(10)

The light receiving device according to (7), in which
the semiconductor layer includes a photoelectric conversion device, and
a protruding structure of the uneven structure includes a dummy gate electrode in a potential floating state or a state of being fixed at a ground potential, the dummy gate electrode being formed when a gate electrode of a transistor is formed, the transistor being used for drive of a corresponding one of the pixels including the photoelectric conversion device.
   (11)

The light receiving device according to (7), in which the transmission suppressor includes an uneven structure formed by digging, at predetermined intervals, a plurality of trenches that becomes recessed shapes in the first surface of the semiconductor layer and disposing, at predetermined intervals, a plurality of protruding structures that becomes protruding shapes on the first surface of the semiconductor layer.

(12)

The light receiving device according to (7), in which the uneven structure is formed by providing, on the first surface of the semiconductor layer, at predetermined intervals, a plurality of quadrangular pyramid shapes or inverted quadrangular pyramid shapes including slopes having an inclination angle according to a plane index of a crystal plane of a single crystal silicon wafer that configures the semiconductor layer.

(13)

The light receiving device according to (7), in which the uneven structure is formed of a plurality of polysilicons, and is floated or fixed at a ground potential.

(14)

The light receiving device according to (1), in which
the optical member has the plurality of optical axes,
zero-order light that passes through the plurality of optical axes enters the transmission suppressor, and
the plurality of optical axes is symmetric with respect to a predetermined point of the first surface.
   (15)

The light receiving device according to (14), in which the plurality of optical axes is point-symmetric with respect to the predetermined point.

(16)

The light receiving device according to (14), in which
each of the pixels further includes a multiplication region section that multiplies carriers generated through the photoelectric conversion, and
the predetermined point includes a point configured within a light incident-side surface of the multiplication region section.
   (17)

The light receiving device according to (1), in which
the optical member includes any one of two on-chip lenses, four on-chip lenses, eight on-chip lenses, and nine on-chip lenses, and
zero-order light that passes through the plurality of optical axes having incident-side vertex portions of the plurality of on-chip lenses as base points enters the transmission suppressor.
   (18)

The light receiving device according to (17), in which
the optical member includes a lens, and
the optical member includes a transparent material.
   (19)

The light receiving device according to (17), in which
the optical member includes a lens, and
the optical member includes an inorganic substance.
   (20)

The light receiving device according to (1), in which each of the pixels further includes a reflection suppressor that suppresses reflection of the light on a light incident-side surface of the semiconductor layer.

(21)

An electronic apparatus including the light receiving device described in (1).

The embodiment of the present invention is not limited to the above-described individual embodiments and may include various modifications that may be arrived at by a person skilled in the art. The effects of the present disclosure are also not limited to the descriptions given above. That is, various additions, changes, and partial deletions are possible in a range that does not depart from the general concept and gist of the present disclosure, which are derived from the descriptions recited in the scope of claims and the equivalents thereof.

The present application claims the benefit of Japanese Priority Patent Application JP2022-030028 filed with the Japan Patent Office on Feb. 28, 2022, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A light receiving device comprising a plurality of pixels, each of the pixels including:
a multifocal optical member having a plurality of optical axes;
a semiconductor layer that receives light that is in a predetermined wavelength range and has passed through the optical member, to perform photoelectric conversion; and
a transmission suppressor that suppresses, on a first surface, on a side opposite to a light incident side, of the semiconductor layer, transmission of the light through the semiconductor layer.

2. The light receiving device according to claim 1, wherein
the optical member includes a plurality of on-chip lenses, and
the optical member has the plurality of optical axes having incident-side vertex portions of the plurality of on-chip lenses as base points, and zero-order light that passes through the plurality of optical axes enters the transmission suppressor.

3. The light receiving device according to claim 1, wherein
each of the pixels further includes a multiplication region section that multiplies carriers generated through the photoelectric conversion, and
on the first surface, the transmission suppressor is configured around the multiplication region section.

4. The light receiving device according to claim 1, wherein the transmission suppressor is configured in a region of the semiconductor layer in which a photoelectric conversion device is disposed, the region excluding a range in which a transistor to be used for drive of a corresponding one of the pixels is disposed.

5. The light receiving device according to claim 1, wherein
the semiconductor layer is configured between the optical member and a wiring layer, and includes:
a first charge detector disposed around a first voltage applicator; and
a second charge detector disposed around a second voltage applicator, and
the transmission suppressor is configured in a region at least excluding the first charge detector and the second charge detector.

6. The light receiving device according to claim 1, wherein
the semiconductor layer includes a photodiode, and
the transmission suppressor is configured to overlap the photodiode in plan view.

7. The light receiving device according to claim 1, wherein the transmission suppressor includes an uneven structure formed on the first surface of the semiconductor layer.

8. The light receiving device according to claim 7, wherein a pitch of the uneven structure is 200 nm or more and 1,000 nm or less.

9. The light receiving device according to claim 7, wherein the uneven structure is formed by digging a plurality of trenches that becomes recessed shapes at predetermined intervals in the semiconductor layer.

10. The light receiving device according to claim 7, wherein
the semiconductor layer includes a photoelectric conversion device, and
a protruding structure of the uneven structure includes a dummy gate electrode in a potential floating state or a state of being fixed at a ground potential, the dummy gate electrode being formed when a gate electrode of a transistor is formed, the transistor being used for drive of a corresponding one of the pixels including the photoelectric conversion device.

11. The light receiving device according to claim 7, wherein the transmission suppressor includes an uneven structure formed by digging, at predetermined intervals, a plurality of trenches that becomes recessed shapes in the first surface of the semiconductor layer and disposing, at predetermined intervals, a plurality of protruding structures that becomes protruding shapes on the first surface of the semiconductor layer.

12. The light receiving device according to claim 7, wherein the uneven structure is formed by providing, on the first surface of the semiconductor layer, at predetermined intervals, a plurality of quadrangular pyramid shapes or inverted quadrangular pyramid shapes including slopes having an inclination angle according to a plane index of a crystal plane of a single crystal silicon wafer that configures the semiconductor layer.

13. The light receiving device according to claim 7, wherein the uneven structure is formed of a plurality of polysilicons, and is floated or fixed at a ground potential.

14. The light receiving device according to claim 1, wherein
the optical member has the plurality of optical axes,
zero-order light that passes through the plurality of optical axes enters the transmission suppressor, and
the plurality of optical axes is symmetric with respect to a predetermined point of the first surface.

15. The light receiving device according to claim 14, wherein the plurality of optical axes is point-symmetric with respect to the predetermined point.

16. The light receiving device according to claim 14, wherein
each of the pixels further includes a multiplication region section that multiplies carriers generated through the photoelectric conversion, and
the predetermined point includes a point configured within a light incident-side surface of the multiplication region section.

17. The light receiving device according to claim 1, wherein
the optical member includes any one of two on-chip lenses, four on-chip lenses, eight on-chip lenses, and nine on-chip lenses, and
zero-order light that passes through the plurality of optical axes having incident-side vertex portions of the plurality of on-chip lenses as base points enters the transmission suppressor.

18. The light receiving device according to claim 17, wherein
the optical member includes a lens, and
the optical member includes a transparent material.

19. The light receiving device according to claim 17, wherein
the optical member includes a lens, and
the optical member includes an inorganic substance.

20. The light receiving device according to claim 1, wherein each of the pixels further includes a reflection suppressor that suppresses reflection of the light on a light incident-side surface of the semiconductor layer.

21. An electronic apparatus comprising the light receiving device of claim 1.
